(19) United States
(12) Patent Application Publication
(10) Pub. No.: US 2012/0080700 A1
(43) Pub. Date: Apr. 5, 2012

(54) LIGHT EMITTING DIODE PACKAGE AND METHOD FOR MANUFACTURING THE SAME

(75) Inventors: CHIEH-LING CHANG, Hsinchu (TW); CHAO-HSIUNG CHANG, Hsinchu (TW)

(73) Assignee: ADVANCED OPTOELECTRONIC TECHNOLOGY, INC., Hsinchu Hsien (TW)

(21) Appl. No.: 13/110,008

(22) Filed: May 18, 2011

(30) Foreign Application Priority Data
Sep. 30, 2010 (CN) 201010298972.5

(51) Int. Cl. H01L 33/52; H01L 33/50

(52) U.S. Cl. 257/98; 438/28; 257/E33.059; 257/E33.061

(57) ABSTRACT

A light emitting diode package comprises a substrate, a light emitting diode chip, an encapsulating layer and a transparent surrounding layer. The surrounding layer is disposed on the substrate and encompasses the encapsulating layer, wherein the hardness of the surrounding layer is greater than the encapsulating layer. A method for manufacturing the light emitting diode package is also provided.

### TECHNICAL FIELD

The disclosure relates generally to a semiconductor device, and more particularly to a light emitting diode package and method for manufacturing the same.

### DESCRIPTION OF THE RELATED ART

Presently, light emitting diodes (LEDs) are widely used in many applications such as lighting or backlight units due to their high efficiency of energy-to-light conversion. Frequently, a transparent encapsulating layer for preventing an LED chip of the LED from damage covers the LED chip. More specifically, as shown in FIG. 1, an LED package 10 in accordance with conventional art comprises a substrate 11, a light emitting diode chip 13 and an encapsulating layer 14, wherein the substrate 11 further comprises a circuit 114. The light emitting diode chip 13 is disposed on one electrode (not label) of the circuit 114 and electrically connects to another electrode (not labeled) of the circuit 114 via a conductive wire 131. The encapsulating layer 14 covers the light emitting diode chip 13, the circuit 114 and the conductive wire 131 to prevent from damage or external interference. However, the encapsulating layer 14 is composed of epoxy, silicone or other resin. That is, the encapsulating layer 14 has low abrasion-resistance and lacks sufficient mechanical strength. Hence, it is necessary to provide a new light emitting diode package having high mechanical strength and enhanced abrasion-resistance.

### BRIEF DESCRIPTION OF THE DRAWINGS

FIG. 1 is a cross section of a light emitting diode package in accordance with prior art.

FIG. 2 is a top view of a light emitting diode package in accordance with one embodiment of the disclosure.

FIG. 3 is a cross section taken along line III-III of FIG. 2.

FIG. 4 is a top view of a light emitting diode package in accordance with another embodiment of the disclosure.

FIGS. 5-12 are schematic diagrams showing different steps of the method in manufacturing the light emitting diode package of the disclosure.

FIG. 13 is a schematic view showing a plurality of interlaced trenches on an encapsulating layer in the manufactured process of the light emitting diode package of the disclosure.

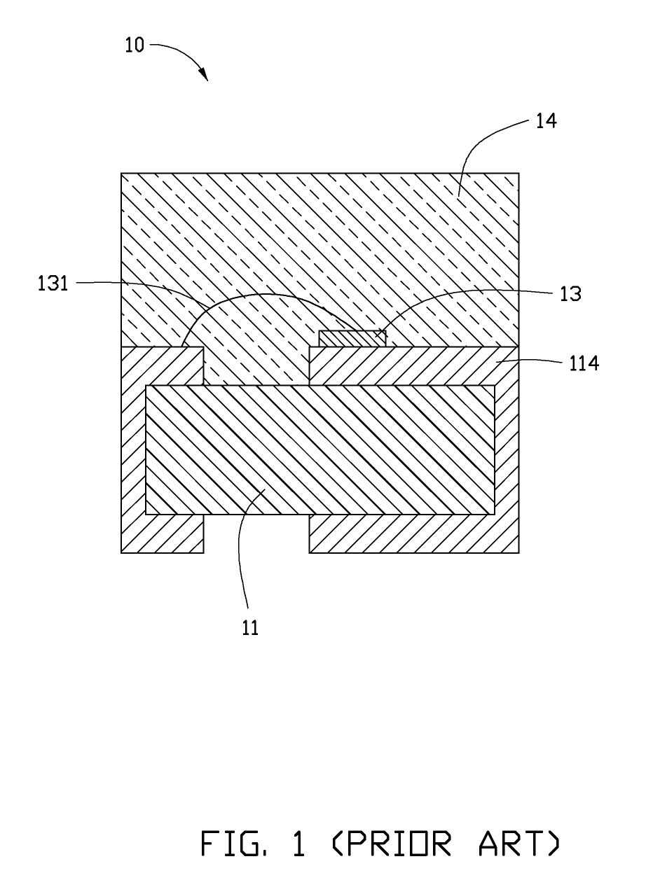

### DETAILED DESCRIPTION

Reference will now be made to the drawings to describe the exemplary embodiments in detail.

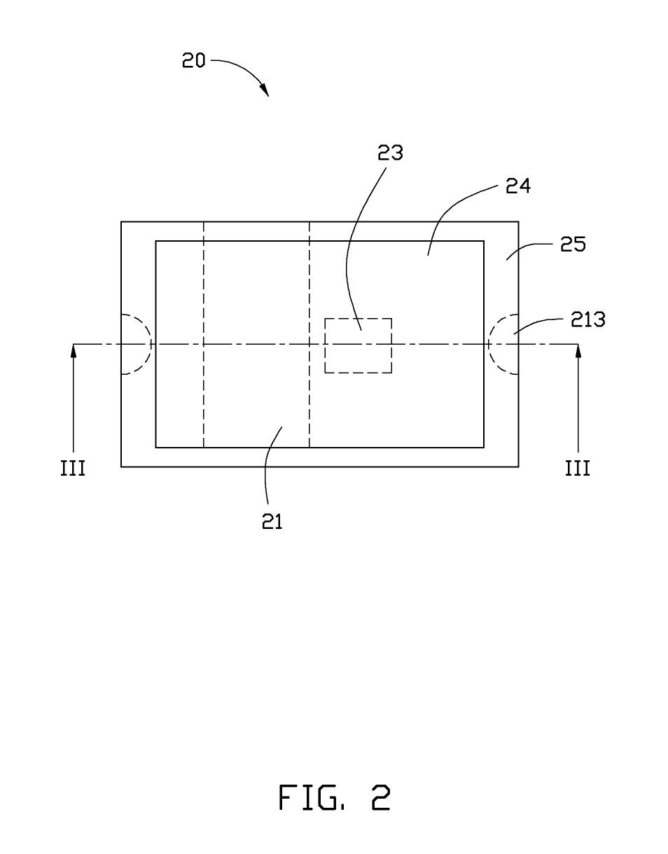

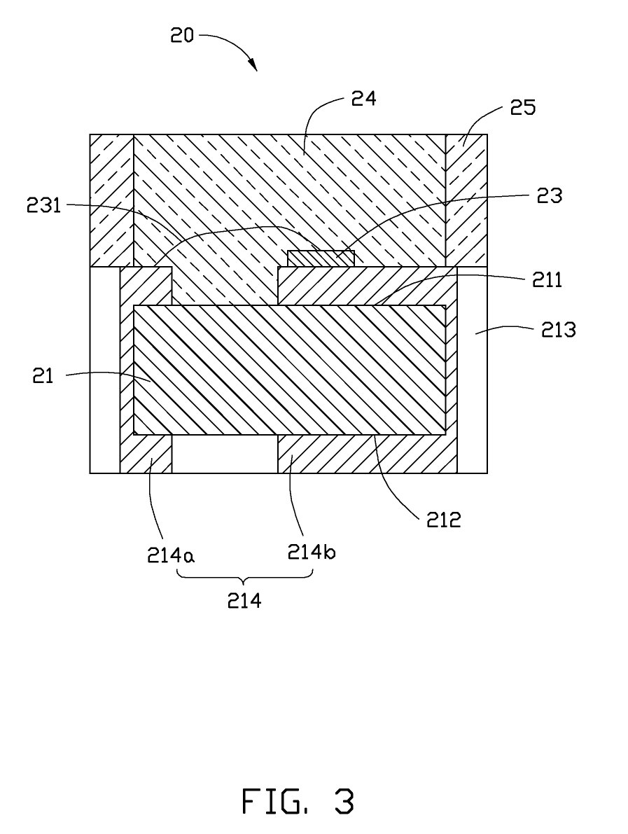

Referring to FIG. 2 and FIG. 3, the present exemplary embodiment provides a light emitting diode package 20 comprising a substrate 21, a light emitting diode chip 23, an encapsulating layer 24 and a surrounding layer 25.

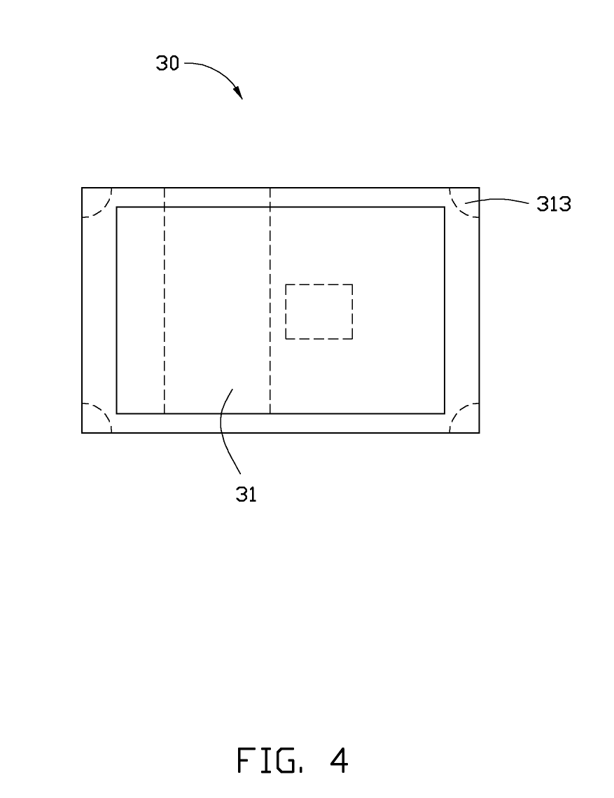

The substrate 21 is used for bearing the light emitting diode package 20, comprising a first surface 211 and a second surface 212 opposite to the first surface 211. Further, at least two tunnels 213 penetrate through the substrate 21 from the first surface 211 to the second surface 212. In the disclosure, the substrate 21 comprises two tunnels 213 respectively disposed on two opposite fringes of the substrate 21, wherein each of the tunnels 213 is defined as semi-circular. In another embodiment of the disclosure as shown in FIG. 4, the substrate 31 comprises four tunnels 313 respectively located on four corners of the substrate 31, wherein each of the tunnels 313 is defined as a quarter circle. Accordingly, the tunnels 313 can be used to orientate the light emitting diode package 30, and to make the substrate 31 without incisive corners.

Referring to FIG. 2 and FIG. 3, the substrate 21 further comprises a circuit 214 having a first electrode 214a and a second electrode 214b, wherein the first electrode 214a and the second electrode 214b respectively extend from the first surface 211 to the second surface 212 via the corresponding tunnels 213. The light emitting diode chip 23 is disposed on the second electrode 214b and electrically connects to the first electrode 214a via at least one conductive wire 231. Alternatively, the electrical connection between the light emitting diode chip 23 and the circuit 214 also can be achieved by flip chip or eutectic (not shown).

The encapsulating layer 24 covers the substrate 21, the light emitting diode chip 23 and the conductive wire 231. In the embodiment, the encapsulating layer 24 is epoxy, silicone or any transparent resin. Alternatively, the encapsulating layer 24 further comprises luminescent conversion element such as phosphor.

The surrounding layer 25 is located on the substrate 21 and encompasses the encapsulating layer 24, wherein the hardness of the surrounding layer 25 is greater than the encapsulating layer 24. In the disclosure, the surrounding layer 25 is transparent and can be composed of PMMA (Polymethylmethacrylate) or PPA (Polyphthalamide), wherein light emitted from the light emitting diode chip 23 is able to pass through the surrounding layer 25 to the outside. Alternatively, the refraction index of the surrounding layer 25 is lower than the encapsulating layer 24 so that light extraction of the light emitting diode package 20 is enhanced. Particularly, the surrounding layer 25 is used for safeguarding the encapsulating layer 24 from damages.

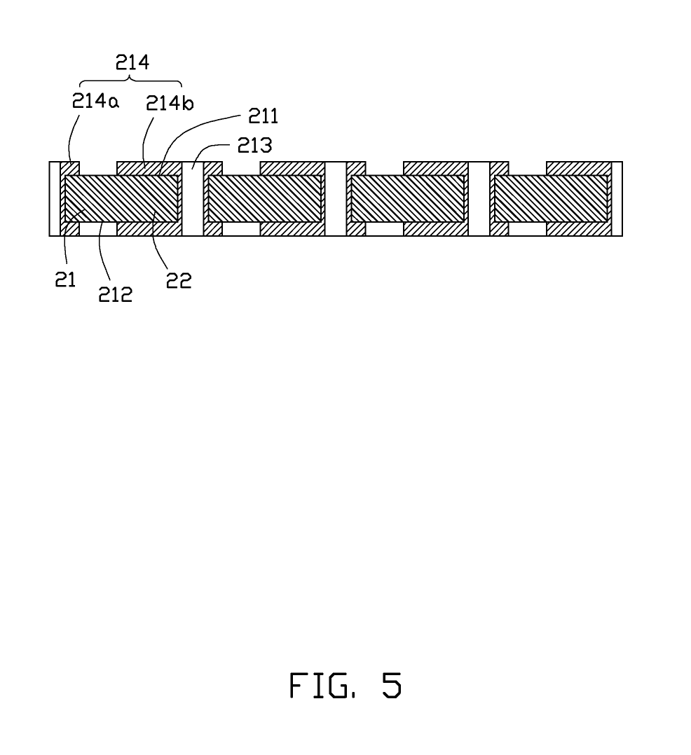

Referring to FIG. 5 to FIG. 12, the disclosure provides a method for manufacturing the light emitting diode package 20, comprising following steps:

As shown in FIG. 5, a base 22 is provided, wherein the base 22 comprises numbers of districts. Each of the districts comprises a substrate 21 and an independent circuit 214. Each of the substrates 21 comprises a first surface 211, a second surface 212 opposite to the first surface 211 and at least two tunnels 213 penetrating through the substrate 21 from the first surface 211 to the second surface 212. In the disclosure, the substrate 21 comprises two tunnels 213 respectively disposed on two opposite fringes of the substrate 21. Each of the independent circuits 214 comprises a first electrode 214a and a second electrode 214b, wherein the first electrode 214a and the second electrode 214b respectively extend from the first surface 211 to the second surface 212 via the two tunnels 213.

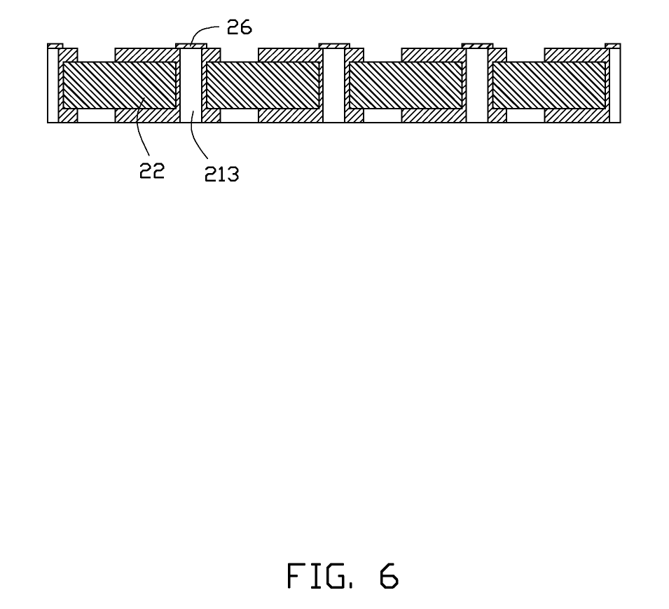

As shown in FIG. 6, a plurality of blocking layers 26 is formed on the base 22, wherein the plurality of blocking layers 26 covers the tunnels 213.

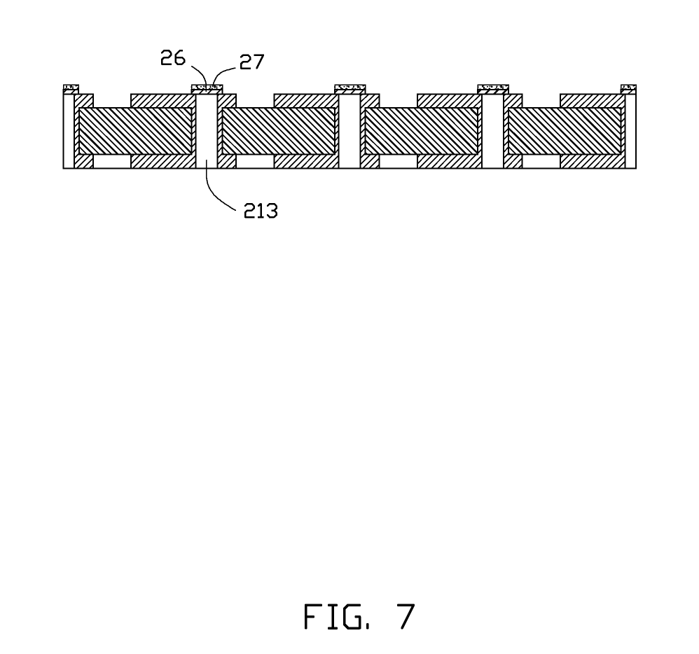

As shown in FIG. 7, a plurality of insulating layers 27 is formed on the plurality of blocking layers 26. The insulating layers 27 are configured for increasing the mechanic strength of the plurality of blocking layers 26.

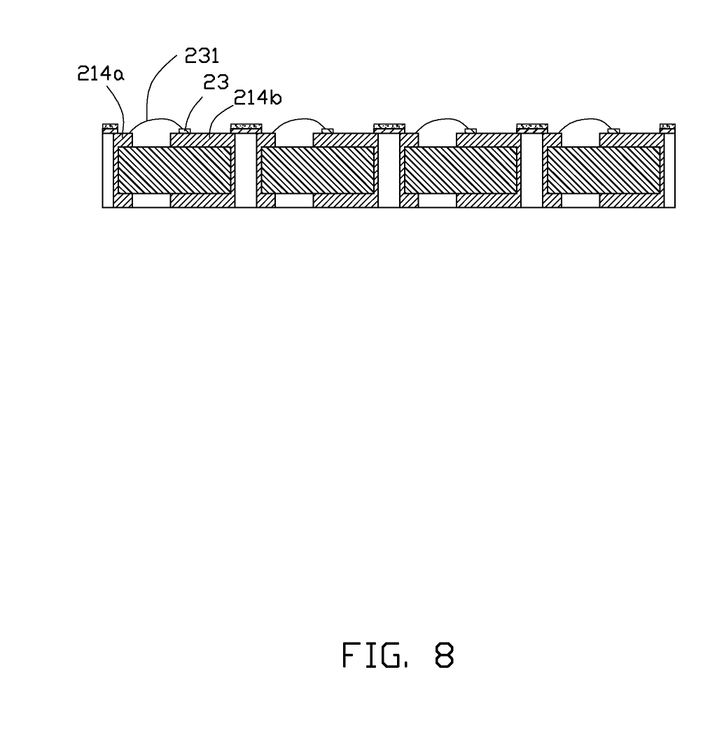

As shown in FIG. 8, a plurality of light emitting diode chips 23 is disposed on the second electrodes 214b and, respectively, electrically connecting to the first electrodes 214a via a plurality of conductive wires 231. Alternatively, the electrical connections between the light emitting diode chips 23 and the circuits 214 also can be achieved by flip chip or eutectic.

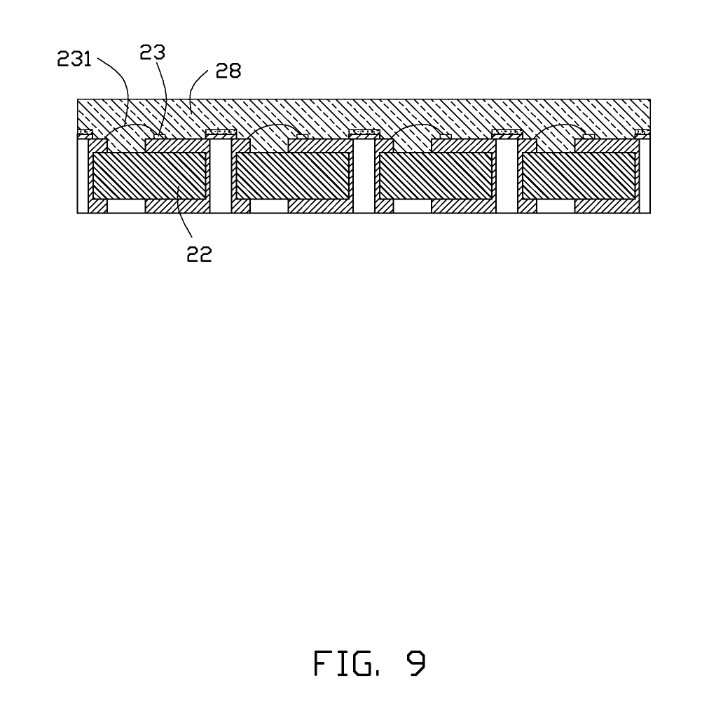

As shown in FIG. 9, an encapsulating layer 28 is disposed on the base 22. The encapsulating layer 28 covers the base 22, the plurality of light emitting diode chips 23 and the conductive wires 231. In the embodiment, the encapsulating layer 28 is epoxy, silicone or any transparent resin. Alternatively, the encapsulating layer 28 further comprises luminescent conversion element such as phosphor.

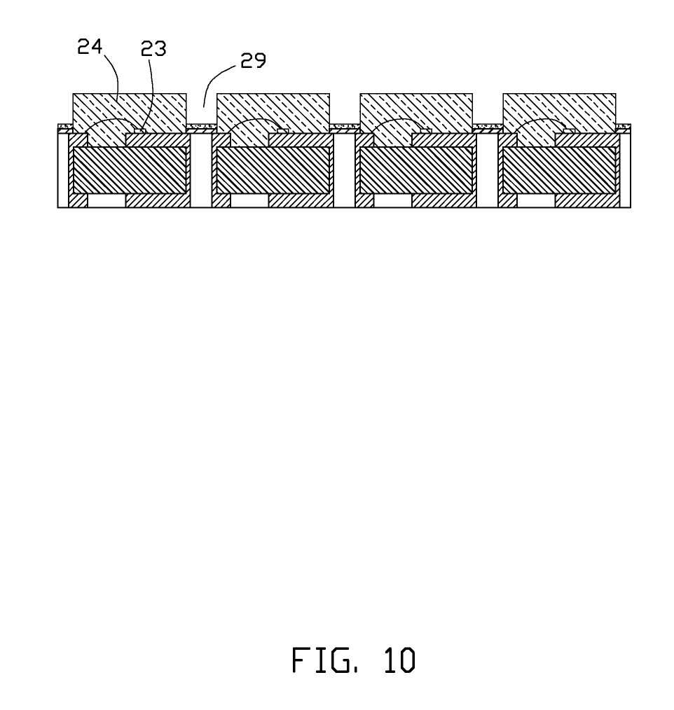

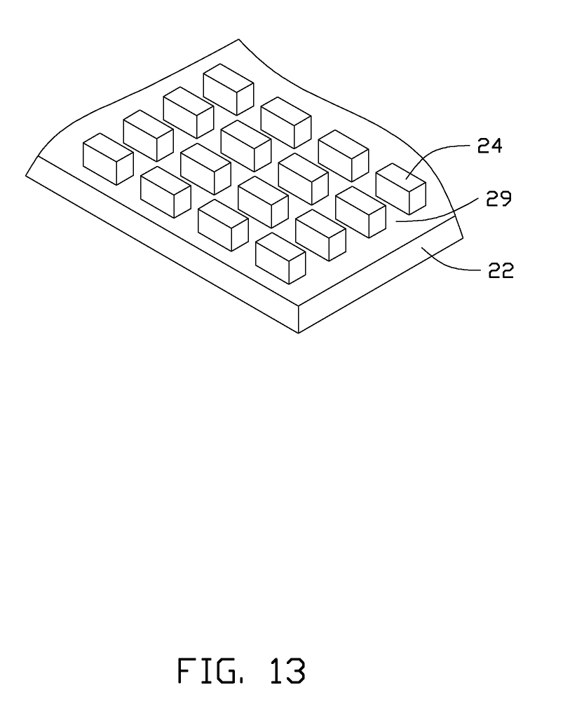

As shown in FIG. 10 and FIG. 13, a plurality of interlaced trenches 29 is formed on the encapsulating layer 28 to divide the encapsulating layer 28 into a plurality of sections 24, wherein each of the sections 24 covers a corresponding light emitting diode chip 23. In the embodiment, the plurality of interlaced trenches 29 can be formed on the encapsulating layer 28 by etching.

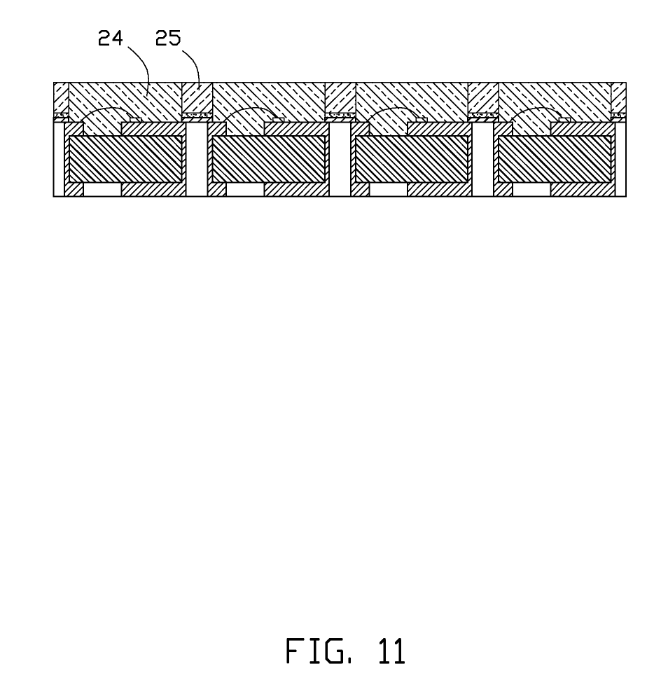

As shown in FIG. 11, a surrounding layer 25 is formed inside the plurality of interlaced trenches 29, wherein the surrounding layer 25 besieges the plurality of sections 24. In the disclosure, the surrounding layer 25 is transparent and can be composed of PMMA or PPA, and the hardness of the surrounding layer 25 is greater than that of each of the plurality of sections 24 of the encapsulating layer 28.

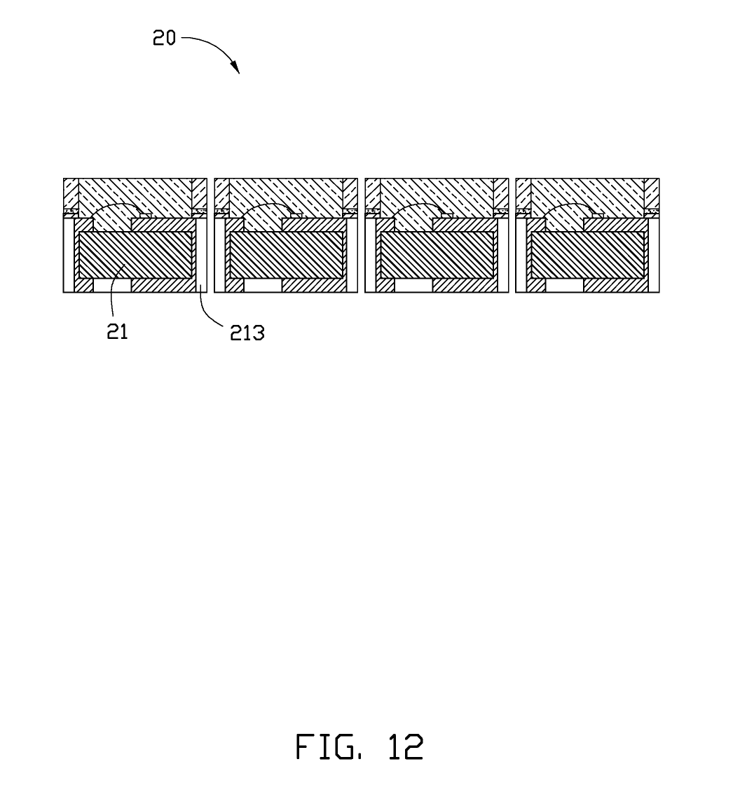

As shown in FIG. 12, the base 22 is sliced along the plurality of interlaced trenches 29 to form numbers of light emitting diode packages 20.

The hardness of the surrounding layer 25 is greater than the encapsulating layer 24, thereby the surrounding layer 25 safeguards the encapsulating layer 24 from damage, and the abrasion-resistant and mechanical strength of the encapsulating layer 24 are also enhanced.

It is to be understood, however, that even though multiple characteristics and advantages of the disclosure have been set forth in the foregoing description, together with details of the structure and function of the invention disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode package, comprising:
a substrate, comprising a first surface, a second surface opposite to the first surface and a circuit;
a light emitting diode chip, electrically connecting to the circuit;
an encapsulating layer, covering the substrate and the light emitting diode chip; and
a transparent surrounding layer, located on the substrate and encompassing the encapsulating layer, wherein a hardness of the surrounding layer is greater than the encapsulating layer, at least a part of light generated by the light emitting diode chip travelling through the encapsulating layer and the transparent surrounding layer to an outside of the light emitting diode package.

2. The light emitting diode package as claimed in claim 1, wherein at least two tunnels penetrate through the substrate, whereby the circuit extends from the first surface to the second surface via the at least two tunnels.

3. The light emitting diode package as claimed in claim 2, wherein there are four tunnels located on the corners of the substrate, and each of the tunnels being defined as a quarter circular.

4. The light emitting diode package as claimed in claim 1, wherein the circuit comprises a first electrode and a second electrode, the light emitting diode chip located on the second electrode and electrically connecting the first electrode via at least one conductive wire.

5. The light emitting diode package as claimed in claim 1, wherein the encapsulating layer further comprises luminescent conversion element.

6. The light emitting diode package as claimed in claim 1, wherein a refraction index of the transparent surrounding layer is lower than that of the encapsulating layer.

7. A method for manufacturing a light emitting diode package, comprising following steps:
providing a base containing numbers of districts, each district of the base comprising a substrate and an independent circuit;
disposing a plurality of light emitting diode chips each on the substrate and, electrically connecting each of the plurality of light emitting diode chips to a corresponding circuit;
disposing an encapsulating layer on the base, wherein the encapsulating layer covers the plurality of light emitting diode chips;
forming a plurality of interlaced trenches on the encapsulating layer to divide the encapsulating layer into a plurality of sections, wherein each section of the encapsulating layer covers at least one of the light emitting diode chips;
disposing a surrounding layer inside the plurality of interlaced trenches, wherein the surrounding layer encompasses the plurality of sections; and
slicing the base along the plurality of interlaced trenches to form a plurality of light emitting diode packages.

8. The method for manufacturing a light emitting diode package as claimed in claim 7, wherein at least two tunnels penetrate through the substrate to accommodate the independent circuit.

9. The method for manufacturing a light emitting diode package as claimed in claim 8, wherein there are four tunnels each located on one of four corners of the substrate, and each of the tunnels is defined as a quarter circular.

10. The method for manufacturing a light emitting diode package as claimed in claim 8, further comprising a step of forming a plurality of blocking layers covering the tunnels.

11. The method for manufacturing a light emitting diode package as claimed in claim 10, further comprising a step of forming a plurality of insulating layers each on one of the plurality of blocking layers.

12. The method for manufacturing a light emitting diode package as claimed in claim 7, wherein the plurality of interlaced trenches is formed on the encapsulating layer by etching.

13. The method for manufacturing a light emitting diode package as claimed in claim 7, wherein the surrounding layer has a hardness larger than that of the insulating layer.

14. The method for manufacturing a light emitting diode package as claimed in claim 13, wherein the surrounding layer is made of one of PMMA (Polymethylmethacrylate) and PPA (Polyphthalamide).
